(19) United States
(12) Patent Application Publication
(10) Pub. No.: US 2009/0235973 A1
(43) Pub. Date: Sep. 24, 2009

(54) Positioning system for solar panels

(76) Inventor: Samuel L. Thomasson, Gilbert, AZ (US)

Correspondence Address: Paul F. Wille, 6407 East Clinton St., Scottsdale, AZ, 85254, US

(21) Appl. No.: 12/077,344

(22) Filed: Mar. 18, 2008

(51) Int. Cl. H01L 31/048

(52) U.S. Cl. 136/246

(57) ABSTRACT

A system for positioning a solar panel includes a first frame and a second frame substantially parallel with the first frame. A plurality of tubes intersect the first frame and extend through the second frame. Each tube has a free end and a distal end. A photovoltaic device attached to the free end of each tube and the distal end is coupled to the first frame. Relative motion of the frames tilts the tubes and the photovoltaic devices, thereby permitting the photovoltaic devices to track the sun during the day.

### FIELD OF THE INVENTION

This invention relates to photovoltaic (PV) solar panels and, in particular, to a mechanism for positioning solar panels approximately normal to incident sunlight.

### BACKGROUND OF THE INVENTION

As known in the art, the intensity of sunlight varies as the cosine of the angle of incidence. That is, maximum intensity is when the sun is directly overhead, at 0°. Atmospheric absorption and other factors also affect intensity but these can be ignored for the purposes of describing this invention. The direction to the sun relative to north is known as azimuth and changes continuously during a day. The height of the sun above the horizon is known as altitude and varies throughout the year, tracing out a figure eight if one were to photograph the sun at exactly the same time each day for one year. The horizon is zero degrees for azimuth, whereas directly overhead is zero degrees for angle of incidence.

A variety of mechanisms have been proposed for tracking the azimuth and elevation of the sun to maintain photovoltaic devices normal to incident sunlight. Some mechanisms, such as disclosed in U.S. Pat. Nos. 4,108,019 and 4,505,255, include a parallelogram as part of the mechanism. In both of these disclosures the tracking mechanisms are mechanically complex and use a parallelogram for one axis. A host of other devices have also been proposed in the prior art.

Regardless of mechanism, driving a solar panel has been the object of additional prior art. One proposal uses a separate photosensor or an array of photosensors in a feed back loop for positioning the panel. Another proposal is to use a look-up table containing preset positions. Still others rely on various forms of clock drive for determining position.

In view of the foregoing, it is therefore an object of the invention to provide an improved positioning mechanism for solar panels.

Another object of the invention is to provide a positioning mechanism in which a single apparatus adjusts both azimuth and elevation.

A further object of the invention is to provide a simplified method for operating a positioning mechanism for solar panels.

### SUMMARY OF THE INVENTION

The foregoing objects are achieved by this invention in which a system for positioning a solar panel includes a first frame and a second frame substantially parallel with the first frame. A plurality of tubes intersect the first frame and extend through the second frame. Each tube has a free end and a distal end. A photovoltaic device attached to the free end of each tube and the distal end is coupled to the first frame. Relative motion of the frames tilts the tubes and the photovoltaic devices, thereby permitting the photovoltaic devices to track the sun during the day.

### BRIEF DESCRIPTION OF THE DRAWINGS

A more complete understanding of the invention can be obtained by considering the following detailed description in conjunction with the accompanying drawings, in which:

FIG. 1 illustrates a positioning mechanism constructed in accordance with the invention;

FIG. 2 illustrates a positioning mechanism constructed in accordance with a preferred embodiment of the invention; and

FIG. 3 illustrates a positioning mechanism constructed in accordance with an alternative embodiment of the invention.

### DETAILED DESCRIPTION OF THE INVENTION

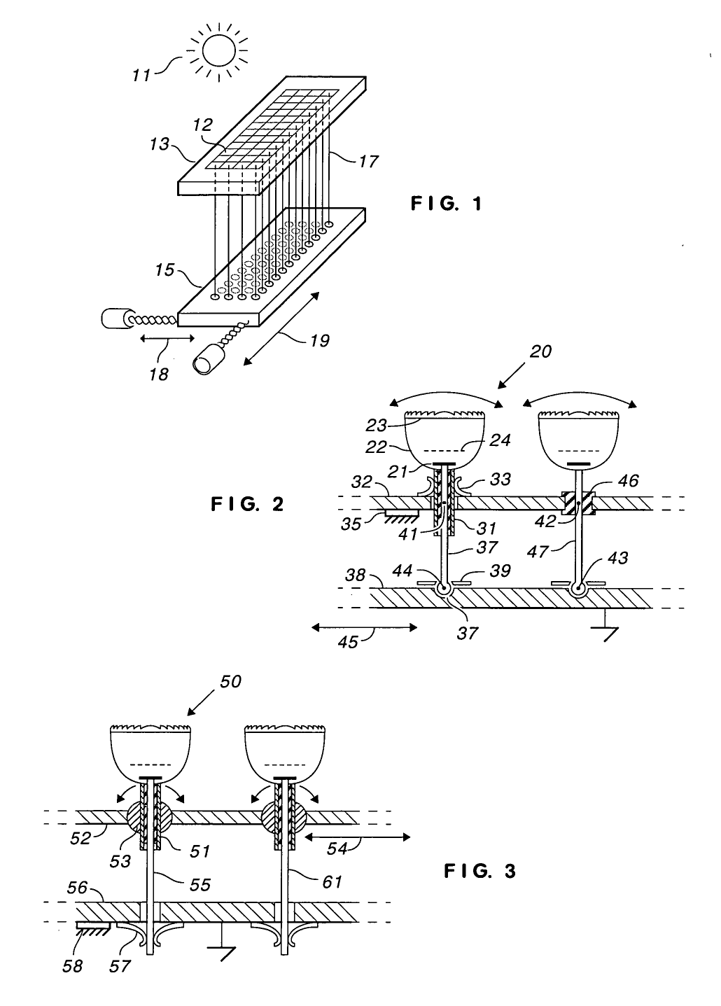

In FIG. 1, light from sun 11 is incident upon array 12 of photovoltaic devices, which convert incident light to electric current. The current is conducted to apparatus (not shown) for storage or use. Array 12 is supported in frame 13. Frame 13 is mechanically coupled to frame 15 by a plurality of movable links 17. In accordance with a first aspect of the invention, frame 13 and frame 15 are moved relative to one another in the directions indicated by arrows 18 and 19, which causes links 17 to tilt the elements of array 12 to face sun 11.

Any suitable drive mechanism can be used, although a screw driven by a stepper motor, as illustrated in FIG. 1, is preferred. For azimuth and elevation, the screws are orthogonal.

FIG. 2 illustrates the operation of the invention in greater detail. Each element of the array, such as element 20, includes photocell 21 located in concentrator 22, including Fresnel lens 23 an diffuser 24. The diffuser prevents the Fresnel lens from creating hot spots on photocell 21. Photocell 21 represents a single wafer or a plurality of devices electrically connected underneath a Fresnel lens. The particular construction of each element is not critical to the invention, although a Fresnel lens, if used, makes proper alignment more critical for obtaining maximum power from the elements. The invention provides a simple mechanism for obtaining the proper alignment.

Concentrator 22 is supported by tube 31, which is located in frame 32 by resilient contacts 33. Contacts 33 include three or more flexible, conductive fingers that couple tube 31 to frame 32 electrically and mechanically. Contacts 33 permit motion along the longitudinal axis of tube 31 and twisting motions relative to the plane of frame 32. In the embodiment illustrated in FIG. 2, frame 32 is relatively fixed, as indicated by support 35, and electrically grounded. Contacts 33 can be located on either the upper surface or the lower surface of frame 32.

The distal end of tube 31 is open and conductive rod 37 extends from photocell 21 through tube 31 to frame 38. Conductive rod 37 is insulated from tube 31 by an insulating sleeve. Tube 31 and rod 37 form a coaxial cable for conducting current from photocell 21 to an electrical load (not shown). As illustrated in FIG. 2, the photocells are connected in parallel. Any combination of series and parallel connections of the photocells can be made. The construction shown provides a simple way to make mechanical and electrical connections to each photocell.

The distal end of rod 37 is spherical or bulbous and rests in socket 37, formed by a suitable recess in frame and collar 39 that traps the bulbous end in the recess. Collar 39 is fastened to frame 38 by any suitable means (not shown) such as adhesive, screws, or bolts.

Points 41, 42, 43, and 44 form a parallelogram, which means that when frame 38 is moved from side to side, as indicated by arrow 45, rods 37 and 47 remain parallel. Frames 32 and 38 remain horizontal, or at some fixed angle, while rods 37 and 47 tilt left or right as frame 38 moves right or left. The elements are spaced to prevent contact during normal use of the positioning mechanism. Rod 47 provides a single electrical connection and is located in frame 32 by resilient insulator 46. A second electrical connection (not shown) can be provided by any suitable means.

Frame 38 can also move into or out of the plane of the drawing, or in any other direction, thereby giving an x-y motion to points 43 and 44. This motion is used to provide control of azimuth and elevation for the array of photocells. As measured along a tube, any motion of frame 38 will increase at least slightly the distance between frame 38 and frame 32. Contacts 33 permits axial motion, eliminating any strain on the tubes, and providing a scrubbing action for improved electrical contact.

In a preferred installation, the frames are positioned in such a way that the sun's rays are normal to the surface at noon on an equinox. This minimizes the amount of motion necessary from rest position (tubes perpendicular to the frames) to track the sun. Even so, because the movable plate can move in any direction, one need not rotate the frame to any particular orientation and any shape frame can be accommodated. This advantage can be very useful in locating an array in an odd corner of a roof, for example. That is, azimuth and elevation are relative and interchangeable with a positioning mechanism constructed in accordance with the invention. In part, this is due to mechanics. In part, this is due to the manner in which the mechanism is operated, in accordance with another aspect of the invention.

One frame is moved relative to the other by monitoring the current from at least one photocell as the array is moved. Suitable software finds maximum current in an x-direction and maximum current in a y-direction. The position is checked periodically, e.g. every quarter hour or half hour, and motion is predicted based upon previous data. Thus, if the last correction was to increase x, then increasing x a little more is likely to be correct. A set up procedure can be invoked when the array is first activated, allowing large changes in position, from which the software can detect suitable initial conditions for each day and store them in semi-permanent or “flash” memory. Thus, the system has a starting position each day.

The directions x and y are preferably orthogonal but are otherwise relative. By detecting position each time, the x-direction can be NE-SW, for example, rather than north-south or east-west, and the system will operate correctly. If a correction exceeds a preset maximum, either the setup routine is invoked or resort is had to a clock based position or, in extreme overcast, the system chooses one of several preset positions, e.g. mid-morning and mid-afternoon, and does not correct.

A clock-calendar function is not necessary. Most microprocessors have timing circuits. A timed interrupt for taking a reading and correcting position, if necessary, produces data that is stored. If a reading is taken approximately every half hour, then, for example, there are twenty-four positions stored. Mid-morning and mid-afternoon are simply the eighth and sixteenth positions. One could choose any position one wanted but choosing two positions approximately ninety degrees apart should produce a detectable difference in current even during extreme overcast. The electric current tested for positioning preferably comes from the array itself. A secondary photocell dedicated to positioning can be used instead.

FIG. 3 illustrates a positioning mechanism constructed in accordance with an alternative embodiment of the invention. Element 50 is constructed similarly to element 20 and is supported by tube 51, which is located in frame 52 by conductive bearing 53. Bearing 53 permits rotational motion or pivoting relative to the plane of frame 52. In the embodiment illustrated in FIG. 3, frame 52 is movable at least from side to side, as indicated by arrow 54.

Coaxial rod 55 extends through a hole in frame 56 and through contacts 57, which are fastened to frame 56. Contacts 57 permit longitudinal motion and twisting motions relative to the plane of frame 56. Frame 56 is relatively fixed, as indicated by support 58. Contacts 57 can be located on either the upper surface or the lower surface of frame 56.

When frame 52 is moved from side to side, as indicated by arrow 54, rods 55 and 61 remain parallel. Frames 52 and 57 remain horizontal, or at some fixed angle, while rods 55 and 61 tilt left or right as frame 52 moves right or left. The elements are spaced to prevent contact during normal use of the positioning mechanism. Either frame can be grounded. In FIG. 3, frame 56 is grounded.

Frame 52 can also move into or out of the plane of the drawing, or in any other direction, thereby providing motion in at least two directions. This motion provides control of azimuth and elevation for the array of photocells. As measured along a rod, any motion of frame 52 will increase at least slightly the distance between frame 52 and frame 56. Contacts 57 permit axial motion, eliminating any strain. Except for interchanging the moveable and fixed plates, the mechanism illustrated in FIG. 3 operates in the same manner as the mechanism illustrated in FIG. 2. Appropriate clips or retainers for limiting longitudinal motion are not illustrated.

The invention thus provides an improved positioning mechanism for solar panels in which a single apparatus adjusts both azimuth and elevation. The solar panels are mechanically and electrically coupled together in a relatively simple structure that provides both the desired motion and reliable electrical contact. A simplified method for operating the positioning mechanism for solar panels allows the system to detect its own orientation.

Having thus described the invention, it will be apparent to those of skill in the art that various modifications can be made within the scope of the invention. For example, the invention does not require special materials. Acrylic is preferred for Fresnel lenses and aluminum for the frames. The frames need not be a solid sheet but can be an open frame with slats or a lattice with elements at the intersections in the latticework. A concentrator is preferred. The invention is suitable for any solar panel, including a flat array of silicon wafers in a suitable protective cover or a plurality of wafers in a reflective trough type of concentrator. The power available from an array without a concentrator is less than the power available from an array using some form of concentration, whether reflective or refractive. Trapped spheres can be used for all bearings. Rectangular bearings are merely for illustration to emphasize the longitudinal motion permitted. Oil absorbing, bronze bearings are preferred for durability outdoors, if metal bearings are used. Although the same kind of drive can be used for both axes, the screw pitch for elevation can be higher than the screw pitch for azimuth, simply because elevation changes so slowly relative to azimuth. Alternatively, one can obtain many of the benefits of the invention by aligning an array for equinox and changing azimuth only. One could use a solid pin for coupling the photovoltaic elements to the frames and conduct current by separate wire. The manner of attaching the tubes to a frame is not critical as long as it is strong enough for outdoor use. That is, for example, a universal joint could be used instead of a ball and socket joint. Instead of an insulating sleeve inside tube 31, a pair of insulating washers can be used instead. A second conductive tube can be used instead of rod 37. Tube 31, and the other tubes, can provide a protective conduit for wires (not shown) from the photocells. The tubes themselves can be grounded or a separate ground wire can be used. If used as protective conduit, the tubes need not be electrically conductive. The pivoting couplings need not all be identical in a single system, although this is preferred, and the combinations illustrated are not exhaustive. That is, for example, the rods in FIG. 2 could extend through frame 38 and be coupled as illustrated in FIG. 3.

What is claimed as the invention is:

1. A system for positioning a plurality of photovoltaic devices in a solar panel, said system comprising:
a first frame;
a second frame substantially parallel with the first frame;
a plurality of photovoltaic devices;
wherein each photovoltaic device is pivotally mounted to the first frame and to the second frame, whereby relative movement between the first frame and the second frame tilts the photovoltaic devices in unison without tilting either frame, thereby permitting the photovoltaic devices to track the sun during the day.

2. The system as set forth in claim 1 wherein said photovoltaic device includes a concentrator.

3. The system as set forth in claim 2 wherein the concentrator includes a Fresnel lens.

4. The system as set forth in claim 1 and further including a first screw driven and a first stepper motor for rotating the screw, thereby moving the first frame relative to the second frame in a first direction.

5. The system as set forth in claim 4 and further including a second screw driven and a second stepper motor for rotating the screw, thereby moving the first frame relative to the second frame in a second direction.

6. The system as set forth in claim 5 wherein the screws are orthogonal.

7. The system as set forth in claim 1 and further including, for each photovoltaic device:
an elongated member;
wherein the photovoltaic device is pivotally coupled to the first frame by said elongated member, which extends through the first frame and is also pivotally coupled to the second frame.

8. The system as set forth in claim 7 wherein said elongated member is a tube.

9. The system as set forth in claim 8 and further including, for each photovoltaic device:
a coaxial member within said first tube;
wherein the photovoltaic device is pivotally coupled to the first frame by said tube; and
wherein the photovoltaic device is pivotally coupled to the second frame by the coaxial member

10. The system as set forth in claim 9 wherein each tube and each coaxial member is electrically conductive and wherein each tube is electrically insulated from the coaxial member within, thereby providing both mechanical and electrical connections to each photovoltaic device.
